(19) United States
(12) Patent Application Publication
(10) Pub. No.: US 2008/0218061 A1
(43) Pub. Date: Sep. 11, 2008

(54) PIXEL STRUCTURE OF ORGANIC ELECTROLUMINESCENT DISPLAY PANEL AND METHOD OF MAKING THE SAME

(76) Inventors: Ching-Ian Chao, Hsin-Chu (TW); Hsia-Tsai Hsiao, Hsin-Chu (TW); Hsien-Hsin Yeh, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 11/755,729

(22) Filed: May 30, 2007

(30) Foreign Application Priority Data
Mar. 7, 2007 (TW) 096107914

(51) Int. Cl. H01J 1/63; H01L 21/77

(52) U.S. Cl. 313/504; 438/129; 257/E21.535

(57) ABSTRACT

A pixel structure of an organic electroluminescent display panel has a plurality of sub-pixel regions. Each of the sub-pixel regions has a plurality of organic luminescent devices electrically connected in series, and the organic luminescent devices disposed in a same sub-pixel region are disposed between a source electrode of a thin film transistor and a voltage source Vdd.

### BACKGROUND OF THE INVENTION

1. Field of the Invention

The present invention relates to a pixel structure of an organic electroluminescent display panel and a method of making the same, and more particularly, to a pixel structure having a plurality of luminescent devices connected in series in sub-pixel regions and a method of making the same.

2. Description of the Prior Art

Organic electroluminescent displays, such as organic light emitting diode (OLED) displays, have advantages of small size, high resolution, high contrast ratio, low power consumption, and active luminescence, which put the organic electroluminescent displays in position to surpass liquid crystal displays as the next generation flat panel display technology.

Please refer to FIG. 1 and FIG. 2. FIG. 1 is a schematic diagram illustrating a structure of a single luminescent device of a conventional organic electroluminescent display panel, and FIG. 2 is a schematic diagram illustrating a driving circuit structure of a pixel structure of a conventional organic electroluminescent active-matrix display panel. As shown in FIG. 1, a luminescent device of the conventional electroluminescent display panel includes a substrate 10 and an anode 12, a hole injection layer 14, a hole transport layer 16, an organic luminescent layer 18, an electron transport layer 20 and a cathode 22, which are disposed on the substrate 10 in that order. The stacked structure described above is a commonly-used structure in the formation of luminescent devices, and luminescent devices utilizing the above-mentioned stacked structure are generally called “normal-type” luminescent devices. Fabrication of the normal-type luminescent device is a mature technology, and has advantages of high yield and high reliability.

Early pixel structures employing the normal-type luminescent device have the following shortcomings when operating with a-Si TFTs produced in an amorphous Si process. As shown in FIG. 2, a driving circuit of the pixel structure employing the normal-type luminescent device includes two thin film transistors T1, T2 and a capacitor C. The thin film transistors T1, T2 can be NMOS thin film transistors. The gate electrode of the thin film transistor T1 is connected to a scan line, and a source electrode and a drain electrode are respectively connected to a data line and a gate electrode of the thin film transistor T2. A source electrode of the thin film transistor T2 is connected to a voltage source Vdd, and a drain electrode of the thin film transistor T2 is connected to an anode 12 of the luminescent device. As shown in FIG. 2, if the NMOS produced by the normal amorphous Si process is used, and the luminescent device is located between the thin film transistor T2 and the voltage source Vss, the disposition affects the threshold voltage of the thin film transistor T2, due to increased device voltage during operation of the luminescent device, so that the current of the thin film transistor T2 becomes unstable. Therefore, in the thin film transistor process of the driving circuit, a PMOS produced by a low temperature poly-silicon (LTPS) process is used to lower the effect of the increased voltage across the luminescent device. However, the LTPS process is more complicated, and panel uniformity suffers. Development of a large substrate is not mature.

Additionally, the single-pixel structure of the conventional electroluminescent display panel only has a single luminescent device, so the driving current of the luminescent device is larger. The large current not only affects the driving stability of the thin film transistor T2, especially for the amorphous thin film transistor with low electron mobility, but also increases power consumption and generates higher thermal energy, which affects the lifetime of the luminescent device.

### SUMMARY OF THE INVENTION

It is therefore an object of the present invention to provide a pixel structure of an organic electroluminescent display panel and a method of making the same.

According to the present invention, a pixel structure of an organic electroluminescent display panel is provided. The pixel structure of the organic electroluminescent display panel comprises a substrate having a thin film transistor region, a first luminescent device region and a second luminescent device region, a thin film transistor disposed in the thin film transistor region of the substrate, a first passivation layer disposed on the substrate having an opening partially exposing the thin film transistor, a first anode disposed on the first passivation layer in the first luminescent device region, a second anode disposed on the first passivation layer in the second luminescent device region, a second passivation layer partially covering the first anode and the second anode so as to partially expose the first anode and the second anode, the exposed first anode having a first luminescent region and a first series-connected region and the exposed second anode having a second luminescent region and a second series-connected region, a pillar substantially disposed on the second passivation layer in the thin film transistor region, the pillar substantially surrounding the first luminescent region and the second luminescent region, an organic luminescent layer covering the first anode in the first luminescent region and the second anode in the second luminescent region, a first cathode covering the organic luminescent layer in the first luminescent region and a part of the first passivation layer in the thin film transistor region and electrically connected to the thin film transistor through the opening of the first passivation layer, a second cathode covering the organic luminescent layer in the second luminescent region and electrically connected to the first series-connected region, and a common cathode covering outside the second luminescent region and electrically connected to the second series-connected region and a voltage source Vdd.

According to the present invention, a method of making an organic electroluminescent display panel is provided. First, a substrate having a plurality of pixel regions and a plurality of thin film transistors is provided, and each of the thin film transistors respectively is disposed in each of the pixel regions. Next, a first passivation layer is formed on the substrate, and the first passivation layer corresponds to each of the thin film transistors, having an opening exposing at least part of each of the thin film transistors. Then, a plurality of anodes is formed in each of the pixel regions. A second passivation layer is formed on the first passivation layer and the anodes, and the second passivation layer partially exposes each of the anodes, so as to form a luminescent region and a series-connected region on each of the anodes. Subsequently, a plurality of pillars are formed on the second passivation layer, and each of the pillars divides each of the pixel regions into a plurality of sub-pixel regions, and each of the anodes located in each of the sub-pixel regions corresponds to each of the anodes, respectively. Next, an organic luminescent layer is formed on the anodes, and the organic luminescent layer forms a plurality of organic luminescent patterns isolated from each other on the anodes through the pillars. Each of the organic luminescent patterns corresponds to each of the anodes, respectively. Last, a cathode layer is formed on the organic luminescent layer, and the cathode layer forms a plurality of cathodes. Each of the cathodes corresponds to each of the organic luminescent patterns, respectively, and the cathodes are isolated from each other on the organic luminescent patterns through the pillars, so as to form a plurality of organic luminescent devices. In each of the pixel regions, the cathode in the sub-pixel region is in contact with the series-connected region of the adjacent anode, and the cathode in another sub-pixel region is in contact with the adjacent thin film transistor, so that the organic luminescent devices in each of the pixel regions are connected to the thin film transistor in series.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a structure of a single luminescent device of a conventional organic electroluminescent display panel.

FIG. 2 is a schematic diagram illustrating a driving circuit structure of a pixel structure of a conventional organic electroluminescent active-matrix display panel.

FIG. 3 is a schematic diagram illustrating a driving circuit structure of a pixel structure of an organic electroluminescent display panel according to a preferred embodiment of the present invention.

FIG. 4 through FIG. 9 are schematic diagrams illustrating a method of making an organic electroluminescent display panel and a pixel structure thereof according to a preferred embodiment of the present invention.

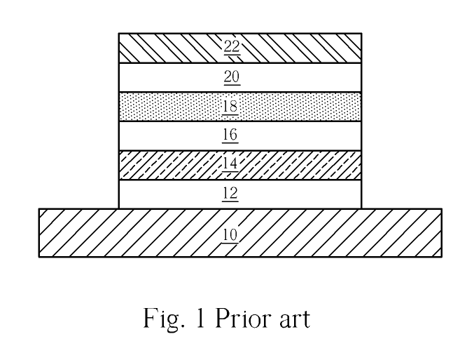

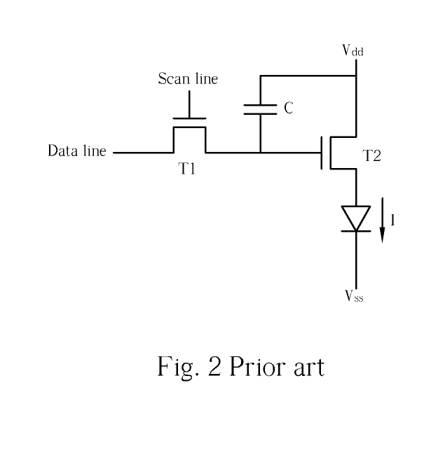

### DETAILED DESCRIPTION

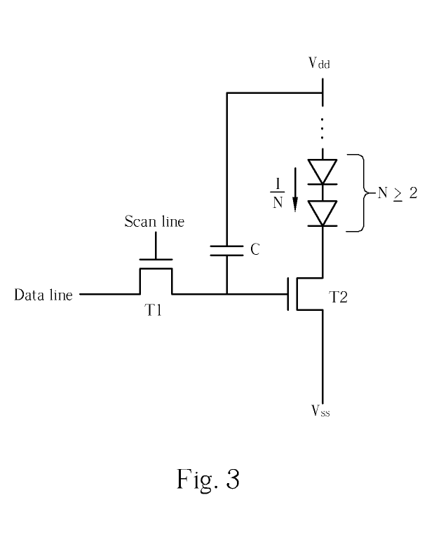

Please refer to FIG. 3. FIG. 3 is a schematic diagram illustrating a driving circuit structure of a pixel structure of an organic electroluminescent display panel according to a preferred embodiment of the present invention. As shown in FIG. 3, the driving circuit structure of the pixel structure according to this embodiment includes two thin film transistors T1, T2 and a capacitor C. The thin film transistors T1, T2 are, for instance, NMOS thin film transistors. The gate electrode of the thin film transistor T1 is connected to a scan line, and the drain electrode and the source electrode are respectively connected to a data line and the gate electrode of the thin film transistor T2. The source electrode of the thin film transistor T2 is connected to a plurality of luminescent devices, and the drain electrode of the thin film transistor T2 is connected to a voltage source Vss. The differences between the pixel structure of this embodiment and the conventional pixel structure are twofold. First, in this embodiment, the luminescent device is located between the voltage source Vdd and the drain electrode of the thin film transistor T2, so as to reduce the effect of the increased voltage across the luminescent device on the thin film transistor T2, especially for amorphous silicon thin film transistors. Therefore, the stability of the luminescent device can be increased. Second, the pixel structure of this embodiment not only has a luminescent device, but also has at least two luminescent devices connected in series. With more luminescent devices in series, the driving current required is largely reduced. For example, two series luminescent devices are used. Compared with the driving current I of the prior art luminescent device, the driving current of each of the luminescent devices in the present invention can be roughly reduced to ½, and the brightness of the display panel is kept the constant. If the number of the luminescent devices in series is N, the driving current of each of the luminescent devices is roughly reduced to I/N. Therefore, reducing current decreases power consumption of the thin film transistor T2, and reduces the temperature of the display panel resulting from thermal energy, so that the lifetime of the luminescent device can be improved.

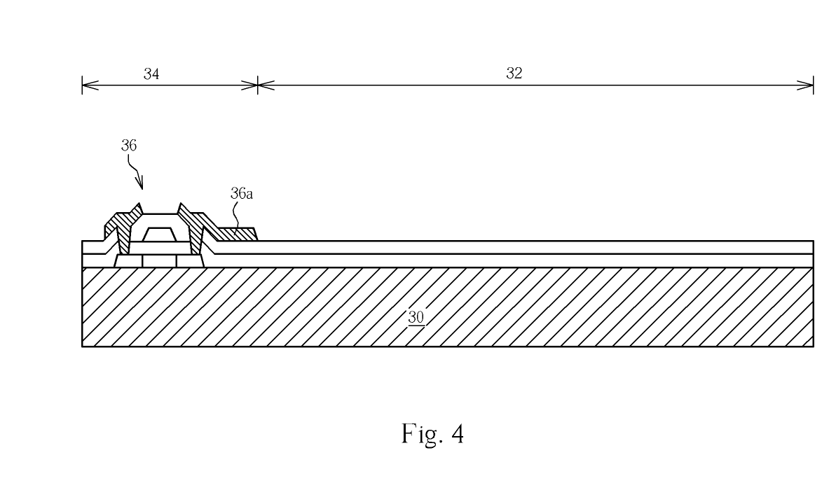

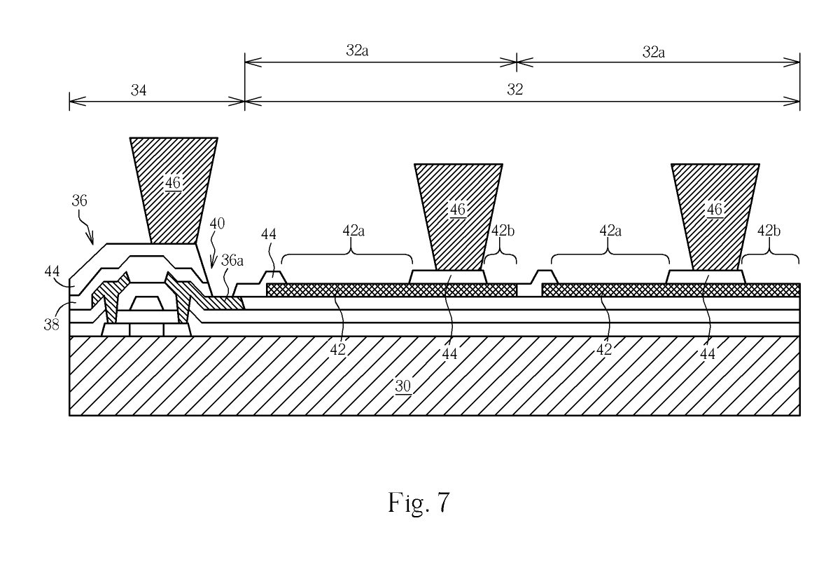

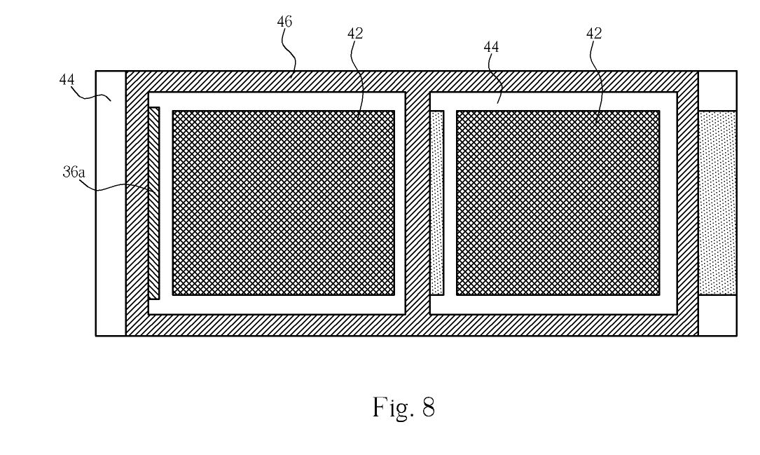

Please refer to FIG. 4 through FIG. 9. FIG. 4 through FIG. 9 are schematic diagrams illustrating a method of making the organic electroluminescent display panel and a pixel structure thereof according to a preferred embodiment of the present invention, wherein FIG. 8 is a top view of a pixel structure shown in FIG. 7. It is worthy of note that this embodiment takes an OLED display panel using amorphous silicon thin film transistors as a switching device as an example to describe the method of the present invention. The present invention is not limited to this example, and can be applied to make other types of organic electroluminescent display panels, such as organic electroluminescent display panels using thin film transistors produced by low-temperature poly-silicon or solid-phase crystalline (SPC) processes as the switching device. In addition, in order to emphasize the key point of the present invention, the figure only shows a pixel structure. As shown in FIG. 4, first, a substrate 30 is provided, such as a glass substrate, and the substrate 30 includes a plurality of pixel regions 32 and a plurality of thin film transistor regions 34. Next, a thin film transistor 36 is fabricated on the substrate 30 in each of the thin film transistor regions 34. The process used for fabricating the thin film transistor 36 is well known in the art, so the process is not described further.

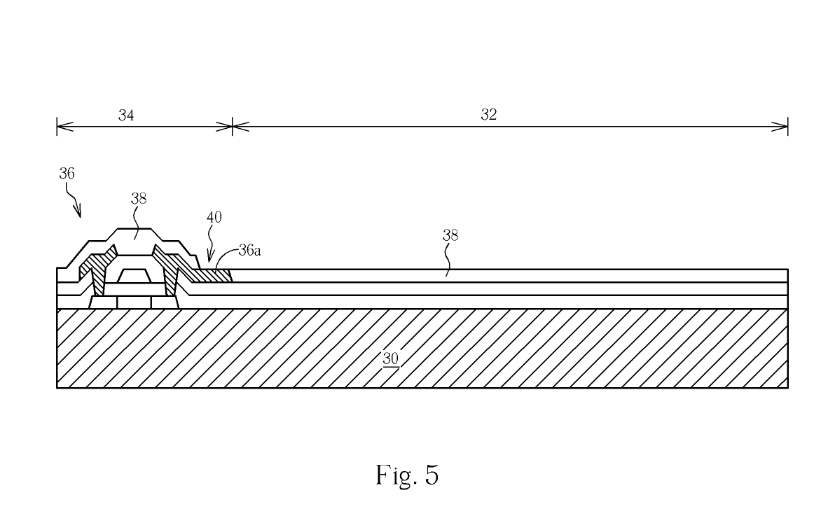

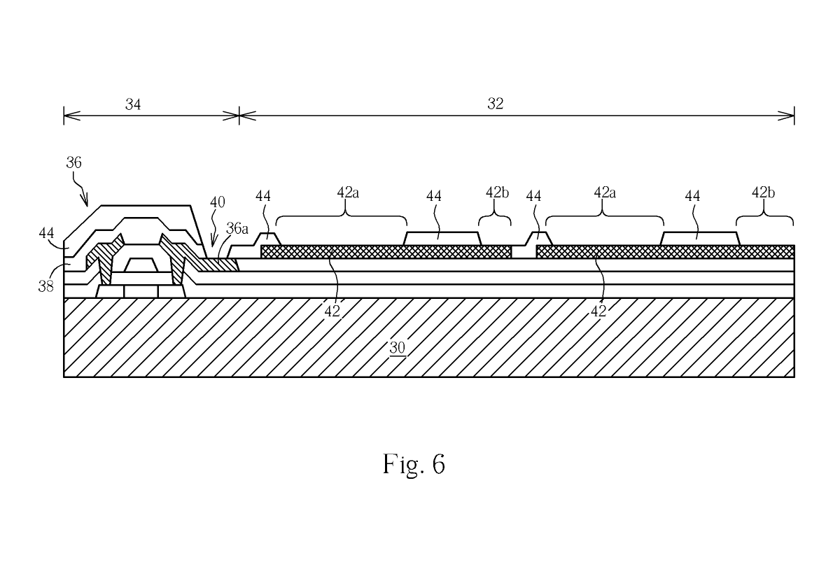

As shown in FIG. 5, a first passivation layer 38 is then formed on the substrate 30. The first passivation layer 38 forms a plurality of openings 40 respectively corresponding to each of the thin film transistors 36. Each of the openings 40 exposes the drain electrode 36a of each of the thin film transistors 36. As shown in FIG. 6, a plurality of anodes 42 is formed in each pixel region 32. This embodiment takes a bottom-emission type organic electroluminescent display panel as an example to describe the method of the present invention, so the material of the anodes 42 is a transparent conductive material, such as indium-tin oxide (ITO), indium-zinc oxide (IZO), aluminum-zinc oxide (AZO), or combinations thereof. The present invention can also be applied to making an organic electroluminescent display panel of the top-emission type, and the material of the anodes 42 in this situation would be metal. Subsequently, a second passivation layer 44 is formed on the first passivation layer 38 and the anodes 42. The second passivation layer 44 partially exposes at least part of each of the anodes 42 to form a luminescent region 42a and a series-connected region 42b on each of the anodes 42. The series-connected region 42b on each of the anodes 42 is located between the luminescent region 42a thereof and the luminescent region 42a of the adjacent anode 42. In addition, the second passivation layer 44 does not cover the openings 40 of the first passivation layer 38.

As shown in FIG. 7 and FIG. 8, a plurality of pillars 46 are then formed on the second passivation layer 44. Each of the pillars 46 divides each of the pixel regions 32 into a plurality of sub-pixel regions 32a. Each of the anodes 42 is located in each of the corresponding sub-pixel regions 32a. In this embodiment, the top view of each of the pillars 46 shows a plurality of circular structures (as shown in FIG. 8), and the number of the circular structures is determined according to the number of the sub-pixel regions 32a divided by each of the pixel regions 32.

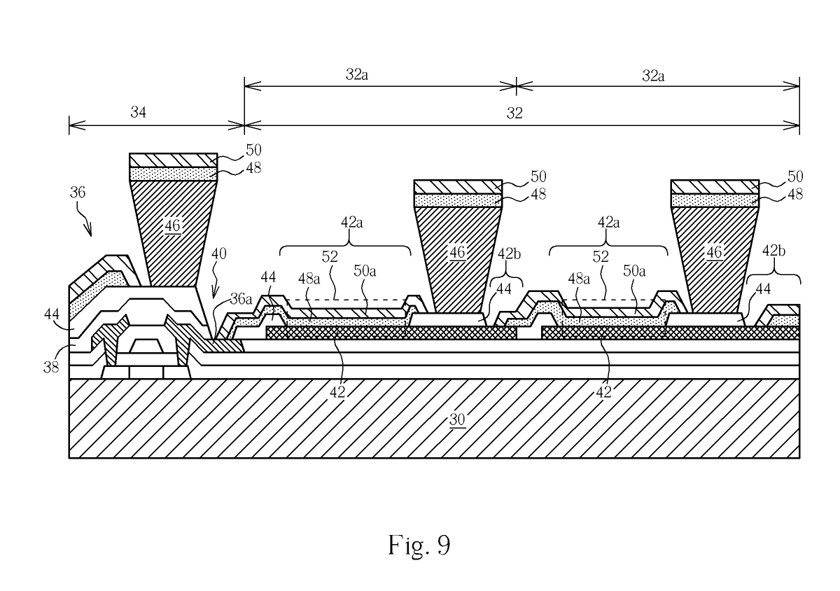

As shown in FIG. 9, an organic luminescent layer 48 is subsequently formed on the anodes 42. The organic luminescent layer 48 forms a plurality of organic luminescent patterns 48a on the anodes 42 which are isolated from each other through the pillars 46. Each of the organic luminescent patterns 48a respectively corresponds to each of the anodes 42. Next, a cathode layer 50 is formed on the organic luminescent layer 48, and similarly, the cathode layer 50 forms a plurality of cathodes 50a on the organic luminescent patterns 48a through the pillars 46. Each of the cathodes 50a respectively corresponds to each of organic luminescent patterns 48a, so an organic luminescent device 52 is formed in each of the sub-pixel regions 32a. The organic luminescent layer 48 can comprise different organic luminescent materials depending on whether the pixel region 32 is a red pixel region, a green pixel region, or a blue pixel region. In addition, if the organic electroluminescent display panel is bottom-emission type, the material of the cathode layer 50 will comprise metal, such as aluminum, lithium, calcium, magnesium, barium, or combinations thereof. If the organic electroluminescent display panel of top-emission type is required, the material of the cathode layer 50 will comprise a transparent conductive material.

Beyond dividing each of the pixel regions 32 into a plurality of sub-pixel regions 32a, the pillars 46 of this embodiment also function to define patterns and to prevent from the contact damage of metal mask. In addition, the cathode 50a in each of the sub-pixel regions 32a can be in direct contact with the series-connected region 42b of the anode 42 in the adjacent sub-pixel region 32a. The cathode 50a in the sub-pixel region 32a adjacent to the thin film transistor 36 may be in direct contact with the drain electrode 36a of the thin film transistor 36 through the opening 40 of first passivation layer 38. Therefore, the organic luminescent devices 52 in each of the pixel regions 32 can be connected to the thin film transistor 36 in series. In addition, the cathode 50a located on the series-connected region 42b of the other side of the anode 42 corresponding to the thin film transistor 36 is electrically connected to a voltage source Vdd.

In order to improve electrical connecting of each of the organic luminescent devices 52, the pillar structure of this embodiment has the several special characteristics. First, the vertical cross-sectional shape of the pillar is trapezoidal, having an upside that is larger than a downside. And, each of the pillars has a top surface and an inclined side surface connected to the top surface. In this embodiment, the top surface and the inclined side surface form an included angle in a range of 40 degrees to 90 degrees, preferably in a range of 40 degrees to 70 degrees. In addition, each of the pillars 46 substantially covers at least part of the corresponding series-connected region 42b, and a width of each of the pillars 46 is in a range of 5 μm to 20 μm, but 10 μm is preferred, and a height of the pillar 46 is in a range of 1 μm to 3 μm.

In summary, each of the pixel regions of the pixel structure of the organic electroluminescent display panel of the present invention has a plurality of organic luminescent devices in series. The organic luminescent devices are located between the source electrode of the thin film transistor and the voltage source Vdd, so as to have advantages of low current and high stability. In addition, each of the anodes has a series-connected region. Combined with the disposition of the pillars, the method of the present invention disposes the organic luminescent devices between the source electrode of the thin film transistor and the voltage source Vdd and connects them in series without changing the process of the normal-type luminescent device. Therefore, the present invention can be applied to a TFT substrate in an a-Si process, and has great development potential for reducing complexity and increasing panel size.

Those skilled in the art will readily observe that numerous modifications and alterations of the device and method may be made while retaining the teachings of the invention.

What is claimed is:

1. A pixel structure of an organic electroluminescent display panel, comprising:
a substrate having a thin film transistor region, a first luminescent device region, and a second luminescent device region;
a thin film transistor disposed in the thin film transistor region of the substrate;
a first passivation layer disposed on the substrate having an opening partially exposing the thin film transistor;
a first anode disposed on the first passivation layer in the first luminescent device region;
a second anode disposed on the first passivation layer in the second luminescent device region;
a second passivation layer partially covering the first anode and the second anode so as to partially expose the first anode and the second anode, the exposed first anode having a first luminescent region and a first series-connected region and the exposed second anode having a second luminescent region and a second series-connected region;
a pillar substantially disposed on the second passivation layer in the thin film transistor region, the first luminescent device region and the second luminescent device region, the pillar substantially surrounding the first luminescent region and the second luminescent region;
an organic luminescent layer covering the first anode in the first luminescent region and the second anode in the second luminescent region;
a first cathode covering the organic luminescent layer in the first luminescent region and a part of the first passivation layer in the thin film transistor region, and electrically connected to the thin film transistor through the opening of the first passivation layer; and
a second cathode covering the organic luminescent layer in the second luminescent region and electrically connected to the first series-connected region.

2. The pixel structure of claim 1, wherein the second series-connected region is electrically connected to a voltage source Vdd.

3. The pixel structure of claim 1, wherein a vertical cross-sectional shape of the pillar is trapezoidal, having an upside that is wider than a downside.

4. The pixel structure of claim 3, wherein the pillar has a top surface and an inclined side surface connected to the top surface, and the top surface and the inclined side surface form an included angle in a range of 40 degrees to 90 degrees.

5. The pixel structure of claim 3, wherein the pillar substantially covers at least part of the first series-connected region.

6. The pixel structure of claim 1, wherein the first series-connected region is located between the first luminescent region and the second luminescent region.

7. The pixel structure of claim 1, wherein a width of the pillar is in a range of 5 μm to 20 μm.

8. The pixel structure of claim 1, wherein a height of the pillar is in a range of 1 μm to 3 μm.

9. The pixel structure of claim 1, wherein the thin film transistor is an NMOS thin film transistor.

10. The pixel structure of claim 1, wherein the first anode and the second anode comprise indium-tin oxide, indium-zinc oxide, aluminum-zinc oxide, or combinations thereof.

11. The pixel structure of claim 1, wherein the first cathode and the second cathode comprise aluminum, lithium, calcium, magnesium, barium, or combinations thereof.

12. An organic electroluminescent display panel, comprising:
a substrate having a plurality of pixel regions;
a plurality of thin film transistors respectively disposed in each of the pixel regions;
a plurality of pillars disposed in each of the pixel regions for dividing each of the pixel regions into a plurality of sub-pixel regions; and
a plurality of organic luminescent devices respectively disposed in each of the sub-pixel regions, each of the organic luminescent device comprising an anode, an organic luminescent layer, and a cathode disposed on the substrate, wherein the cathode in each of the sub-pixel regions is electrically connected to the anode in each of the adjacent sub-pixel regions in a same pixel region for connecting the organic luminescent devices in the same pixel region to each other in series, and the cathode in a sub-pixel region adjacent to the thin film transistor in the same pixel region is electrically connected to the thin film transistor.

13. The organic electroluminescent display panel of claim 12, wherein each of the anodes has a series-connected region, and the cathode of the sub-pixel region in the same pixel region is in contact with the series-connected region in the adjacent sub-pixel region for electrically connecting to the anode in the adjacent sub-pixel region.

14. The organic electroluminescent display panel of claim 13, wherein a vertical cross-sectional shape of each of the pillars is trapezoidal having an upside that is wider than a downside.

15. The organic electroluminescent display panel of claim 14, wherein each of the pillars has a top surface and an inclined side surface connected to the top surface, and the top surface and the inclined side surface form an included angle in a range of 40 degrees to 90 degrees.

16. The organic electroluminescent display panel of claim 12, wherein a width of each of the pillars is in a range of 5 μm to 20 μm.

17. The organic electroluminescent display panel of claim 12, wherein a height of each of the pillars is in a range of 1 μm to 3 μm.

18. A method of making an organic electroluminescent display panel, comprising:
providing a substrate having a plurality of pixel regions and a plurality of thin film transistors respectively disposed in each of the pixel regions;
forming a first passivation layer on the substrate corresponding to each of the thin film transistors having an opening exposing at least part of each of the thin film transistors;
forming a plurality of anodes in each of the pixel regions;
forming a second passivation layer on the first passivation layer and the anodes for partially exposing each of the anodes to form a luminescent region and a series-connected region on each of the anodes;
forming a plurality of pillars on the second passivation layer for dividing each of the pixel regions into a plurality of sub-pixel regions, wherein each of the anodes is located in each of the corresponding sub-pixel regions;
forming an organic luminescent layer on the anodes to form a plurality of organic luminescent patterns isolated from each other on the anodes through the pillars, each of the organic luminescent patterns respectively corresponding to each of the anodes; and
forming a cathode layer on the organic luminescent layer to form a plurality of cathodes corresponding to each of the organic luminescent patterns, isolated from each other on the organic luminescent patterns through the pillars to form a plurality of organic luminescent devices, wherein in each of the pixel regions, the cathode in the sub-pixel region is in contact with the series-connected region of the adjacent anode, and the cathode in another sub-pixel region is in contact with the adjacent thin film transistor to connect the organic luminescent devices in each of the pixel regions to the thin film transistor in series.

19. The method of claim 18, wherein the vertical cross-sectional shape of each of the pillars is trapezoidal with an upside that is wider than a downside.

20. The method of claim 18, wherein each of the pillars has a top surface and an inclined side surface connected to the top surface, and the top surface and the inclined side surface form an included angle in a range of 40 degrees to 90 degrees.
